(19) United States
(12) Patent Application Publication
(10) Pub. No.: US 2023/0231073 A1
(43) Pub. Date: Jul. 20, 2023

(54) LIGHT-EMITTING DIODE COMPRISING A SEMICONDUCTOR BASED ON AlN P-DOPED WITH MAGNESIUM ATOMS AND A LAYER OF DOPED DIAMOND

(71) Applicants: COMMISSARIAT A L'ENERGIE ATOMIQUE ET AUX ENERGIES ALTERNATIVES, Paris (FR); C.N.R.S., Paris Cedex 16 (FR); UNIVERSITÉ GRENOBLE ALPES, Saint-Martin-D'Heres (FR)

(72) Inventors: Alexandra-Madalina SILADIE, Grenoble Cedex 09 (FR); Bruno DAUDIN, Grenoble Cedex 09 (FR); Gwénolé JACOPIN, Grenoble Cedex 09 (FR); Julien PERNOT, Grenoble Cedex 09 (FR)

(73) Assignees: COMMISSARIAT A L'ENERGIE ATOMIQUE ET AUX ENERGIES ALTERNATIVES, Paris (FR); C.N.R.S., Paris Cedex 16 (FR); UNIVERSITÉ GRENOBLE ALPES, Saint-Martin-D'Heres (FR)

(21) Appl. No.: 17/768,385

(22) PCT Filed: Oct. 14, 2020
(86) PCT No.: PCT/FR2020/051809

§ 371 Date: Apr. 12, 2022

(30) Foreign Application Priority Data
Oct. 17, 2019 (FR) FR1911616

(51) Int. Cl. H01L 33/02; H01L 33/00; H01L 33/06; H01L 33/14; H01L 33/24; H01L 33/32; H01L 33/42

(52) U.S. Cl. CPC H01L 33/025; H01L 33/007; H01L 33/0095; H01L 33/06; H01L 33/14; H01L 33/145; H01L 33/24; H01L 33/325; H01L 33/42; H01L 2933/0016

(57) ABSTRACT

A light-emitting diode may include: a first n-doped semiconductor portion; a second p-doped semiconductor portion; an active zone disposed between the first and second portions and including at least one emitting semiconductor portion; a layer that is electrically conductive and optically transparent to at least one wavelength of the UV range configured to be emitted from the emitting portion, the layer being such that the second portion is disposed between the layer and the active zone. The semiconductors of the first portion and of the emitting portion may include compounds including nitrogen atoms as well as atoms of aluminum and/or of gallium. The semiconductor of the second portion may include Al_{X2}Ga_{(1-X2-Y2)}In_{Y2}N that is p-doped with magnesium atoms, wherein X2>0, Y2>0, and X2+Y2<1, and in which the atomic concentration of magnesium is greater than 10¹⁷ at/cm³. The electrically conductive layer may include doped diamond.

### TECHNICAL FIELD

The invention concerns the field of LEDs (i.e. light-emitting diodes). Advantageously, the invention applies to the production of LEDs emitting light in the ultra-violet (UV) range.

### STATE OF THE ART

LEDs based on semiconductor heterostructures emitting in the UV range are constituted by a stack of layers comprising AlGaN of various compositions. FIG. 1 is a diagrammatic representation of the structure of such an LED 10. The LED 10 comprises a p-n junction formed by a first layer 12 comprising n-doped AlGaN and a second layer 14 comprising p-doped AlGaN. The LED 10 also comprises, between layers 12 and 14, an active zone 16 forming the emitting region of the LED 10, that is to say the region in which occur the combinations of electrons and electron holes which generate the emission of photons. The active zone 16 comprises AlGaN not intentionally doped. The LED 10 also comprises, on the second layer 14, a strongly p-doped layer 18 layer of GaN, as well as an electrically conductive layer 20 disposed on the layer 18 and for example comprising a bi-layer stack of Ni—Au.

The composition of the semi-conductor of the active zone 16 is chosen as a function of the wavelength to be emitted. To emit in the UV range, the active zone 16 comprises AlₓGa₍₁₋ₓ₎N, with X such that 0≤X≤1. The first layer 12 comprises n-doped Al_{Y1}Ga_{(1-Y1)}N, and the second layer 14 comprises p-doped Al_{Y2}Ga_{(1-Y2)}N, with Y₁>X and Y₂>X.

Ideally, forming layers 12 and 14 with AlN (that is to say formed such that Y₁=1 and Y₂=1) would make it possible to simplify the production of the LED 10. However, forming the second layer 14 to be p-doped with AlN poses a problem since there is no technical solution making it possible to obtain AlN with a level of p-type doping high enough to ensure electrical conduction that is sufficient and necessary for the proper operation of the LED 10. Layers 12 and 14 are thus currently produced such that Y₁<1 and Y₂<1.

The injection of current that must be carried out from the layer 14 side of the LED 10 is another important limitation. This problem is currently solved by virtue of the presence of the layer 18 of strongly p-doped GaN. However, the absorption of the UV radiation emitted from the active zone 16 by that layer 18 limits the efficiency of the LED 10. Moreover, the deposit of the layer 20, required to ensure proper lateral spreading of the current stream lines and optimize the injection of current, contributes to degrading still further the emission efficiency of the LED due to the fact that this layer 20 absorbs part of the UV light emitted from the active zone 16.

In the document “GaN/AlGaN Nanocolumn Ultraviolet Light-Emitting Diode Using Double-Layer Graphene as Substrate and Transparent Electrode” by Ida Marie Hoiaas et al., Nano Lett. 2019, 19, 3, pp. 1649-1658, graphene is used as substrate under the n-doped part of the LED. Strongly p-doped GaN is used at the top of the structure which thus has the same drawbacks as those indicated above.

In the document “InGaN/GaN Core—Shell Single Nanowire Light Emitting Diodes with Graphene-Based P-Contact” by M. Tchernycheva et al., Nano Lett. 2014, 14, 5, pp. 2456-2465, it is proposed to use graphene for contact on a LED formed from a single wire. This solution is well-adapted to the structure of the LED described in that document but is difficult to implement for LEDs of different structures in particular on account of the fragility of the graphene and fluctuations in the height of the wires. Furthermore, the graphene is not deposited by epitaxy and its transfer may prove complicated. Furthermore, the sheet resistance is still high (˜500Ω/□, according to document “Graphene as Transparent Electrodes: Fabrication and New Emerging Applications”, by Y.Xu and J. Liun Small 2016, 12, No. 11, 1400-1419).

Another solution consists of producing the LED such that the light emission takes place from the back face (from the n-doped semiconductor layer side), through a sapphire substrate on which the different layers of the LED are formed. The sapphire substrate is transparent to the emitted UV radiation. However, this limits the design possibilities for the LED.

### DISCLOSURE OF THE INVENTION

An aim of the present invention is to provide a light-emitting diode not having the drawbacks described above, that is to say not requiring the presence of a strongly p-doped GaN layer on the p-doped side of the LED, and for which the design possibilities are not limited by the requirement to produce light emission from the back face of the LED.

For this, a light-emitting diode is provided comprising at least:

a first n-doped semiconductor portion;

a second p-doped semiconductor portion;

an active zone disposed between the first and second portions and comprising at least one emitting semiconductor portion;

wherein

the semiconductors of the first portion and of the emitting portion comprise compounds comprising nitrogen atoms as well as atoms of aluminum and/or of gallium;

the semiconductor of the second portion comprises Al_{X2}Ga_{(1-X2-Y2)}In_{Y2}N that is p-doped with magnesium atoms, with X2>0, Y2>0 and X2+Y2≤1, and in which the atomic concentration of magnesium is greater than 10¹⁷ at/cm³.

An LED is thus provided in which, by virtue of the semiconductor of the second portion comprising _{AlX2Ga}_{(1-X2-Y2})_{lnY2N} that is p-doped with magnesium atoms, a strongly p-doped GaN layer is not required on the p-doped side of the LED given that this semiconductor of the second portion makes it possible to obtain sufficient injection of current and current stream line spreading.

Furthermore, the semiconductor of the second portion does not absorb the UV radiation. The LED provided is thus well-adapted to achieve UV light emission, it being possible to achieve this light emission through the second p-doped semiconductor portion of the LED.

The absence of the highly p-doped GaN layer also represents a simplification for producing the LED.

The presence of indium in the semiconductor of the second portion (which comprises AlGaInN) makes it possible, relative to that same semiconductor not comprising indium (that is to say AlGaN), to incorporate a higher number of doping atoms of magnesium due to the fact that the atomic concentration of magnesium obtained is proportional to the amount of indium present in the semiconductor. Thus, the level of p type doping that can be obtained in the semiconductor of the second portion is greater and makes it possible to obtain sufficient injection of current and current stream line spreading. The presence of indium in the AlN or the AlGaN makes it possible to increase the limited solubility of magnesium in the AlN or the AlGaN, for example by a factor of 10, and thus increases the doping level that can be obtained in this semiconductor.

The possibility of incorporating a greater number of magnesium atoms when the semiconductor comprises indium is unexpected since, when these two types of atoms are added separately to the AlN, they induce a compressive stress. There is thus no reason to expect that their simultaneous addition would be favorable in terms of accumulated plastic energy since the addition of the indium does not contribute to relaxing the elastic stress induced by the addition of the magnesium.

Furthermore, according to the invention, this LED includes at its top a layer that is electrically conductive and optically transparent relative to UV radiation emitted by the LED and which comprises doped diamond. The second portion is disposed between the active zone and that electrically conductive layer. The use of p-doped diamond to form a transparent electrode makes it possible to promote “spreading”, that is to say obtaining an even distribution of the current stream lines over the whole surface of the injection layer of the LED formed by the second portion, which is favorable to the optimization of the emission performance of the LED. The choice of the doped diamond to produce the electrically conductive layer at the top of the LED is furthermore a particularly judicious choice given that this makes it possible to obtain considerably better performance than that obtained with other transparent conductive materials such as conductive transparent oxides in particular on account of the transparency of the diamond in the UV-C range.

The diamond used to form this electrically conductive layer may for example be nanocrystalline diamond, such as polycrystalline diamond.

The doped diamond of this electrically conductive layer is not “Diamond Like Carbon” (DLC). DLC is the name attributed to a variety of amorphous carbon-based materials of which certain properties may resemble diamond (see for example the document “Diamond-like carbon: state of the art” by A. Grill, Diamond and Related Materials Volume 8, Issues 2-5, March 1999, pages 428-434). According to the different methods of production (and percentage of hydrogenation), this material may have a band gap energy comprised between 1.0 and 4.0 eV, which limits its use as a coating to be employed in the infra-red and visible range (see the document mentioned above), but is not suitable for producing an optically transparent layer at least at a wavelength of the UV range. Moreover, although its resistivity may be modulated (10²-10¹⁶Ω/cm⁻¹), it is still high. For this reason, DLCs are used as insulating materials and not as electrically conductive materials (see the document mentioned earlier).

The use of diamond to produce a layer that is electrically conductive and transparent at wavelengths of the UV range is not obvious for the person skilled in the art. First of all, the possibility of strongly doping diamond so as to form an electrically conductive layer is not well known. Furthermore, the person skilled in the art does not consider diamond as a low-cost material and of which the growth conditions (temperature, pressure, sample size) are compatible with the manufacture of a layer that is transparent and conductive for a LED.

The layer of doped diamond also makes it possible to dissipate heat by virtue of the excellent heat conduction properties of diamond. Such a layer of doped diamond also has the advantage of being biocompatible for biomedical applications (for example optogenetics, fluorescence, etc.).

The atomic concentration of magnesium in the semiconductor of the second portion may be greater than 10²⁰ at/cm³. Such an atomic concentration of magnesium is for example obtained when the ratio between the atomic concentration of magnesium and the atomic concentration of indium is comprised between 1 and 20, or between 1 and 50, or possibly between 1 and 100, and preferably of the order of 10.

The semiconductors of the first portion and of the emitting portion may comprise GaN, or AlN, or AlGaN, or InGaN, or AlGaInN.

The LED may be such that:

Y2 is such that 0<Y2 0.01, and/or

the atomic concentration of magnesium in the semiconductor of the second portion is comprised between 10²⁰ at/cm³ and 10²¹ at/cm³.

The above configuration makes it possible to obtain a good level of p-type doping of the semiconductor of the second portion by virtue of the considerable drop in effective ionization energy of the magnesium at such doping levels, and thus good current injection in the LED by virtue of the electrical conduction of the second portion which is close or similar to that of a metallic electrode.

The LED may furthermore comprise:

a third n-doped semiconductor portion such that the second portion is disposed between the third portion and the active zone, and in which the semiconductor of the third portion comprises Al_{X3}Ga_{(1-X3-Y3)}In_{Y3}N, with X3>0, Y3>0 and X3+Y3≤1, and/or

a layer that is electrically conductive and optically transparent to at least one wavelength configured to be emitted from the emitting portion, said layer being such that the second portion is disposed between said layer and the active zone.

The LED may furthermore comprise a third n-doped semiconductor portion disposed between the electrically conductive layer and the second portion, and in which the semiconductor of the third portion comprises Al_{X3}Ga_{(1-X3-Y3)}In_{Y3}N, with X3>0, Y3>0 and X3+V3≤1.

Such a third portion and/or the layer indicated above form a transparent electrode on the structure of the LED which makes it possible to facilitate the establishment of contact while remaining transparent to the emitted wavelength, in particular when this wavelength is in the UV range. Producing the third portion is possible by virtue of the semiconductor of the second portion which is of the same chemical nature as that of the third portion. The third portion makes it possible to achieve injection of current by tunnel effect in the LED. Moreover, the third portion and/or said layer makes it possible to promote “spreading”, that is to say obtaining even distribution of the current stream lines over the whole surface of the injection layer of the LED, which is favorable to optimizing the LED. Furthermore, when the LED comprises at the same time the third portion and the layer that is electrically conductive and optically transparent, the third portion may be disposed between the second portion and said electrically conductive and optically transparent layer.

The layer that is electrically conductive and optically transparent to at least one wave-length configured to be emitted from the emitting portion comprises for example to a diamond layer of thickness less than 150 nm and preferably of the order of 60 nm. The diamond may comprise doped polycrystalline diamond in which the concentration of dopants is for example equal to 2.7×10¹⁹ at/cm³ or more generally comprised between 1×10¹⁵ and 2×10²¹ at/cm³, making it possible to obtain electron conductivity for example comprised between 1.5×10⁻⁸Ω⁻¹m⁻¹ and 75.1Ω⁻¹m⁻¹. The dopants used for example comprise boron atoms. The optical absorption obtained in relation to the wavelength or wavelengths to be emitted from the emitting portion is in this case less than approximately 25% considering for example a layer of doped diamond of thickness approximately equal to 60 nm, with an absorption coefficient varying between 1×10⁴ cm⁻¹and 5×10⁴ cm⁻¹ for a wavelength of 310 nm.

In general terms, the electrically conductive and optically transparent layer has, in relation to the wavelength or wavelengths to be emitted from the emitting portions, an optical absorption less than approximately 25%.

The electrically conductive layer may comprise diamond.

The semiconductor of the first portion may comprise Al_{X1}Ga_{(1-X1)}N, with 0≤X1≤1, preferably with 0.7≤X1≤0.9. The band gap value in this case is greater than that of the active zone.

The semiconductors of the first and second portions may be such that X2=X1.

The semiconductor of the emitting portion may comprise Al_{X4}Ga_{(1-X4)}N, with X4≤0.9.X1. Thus, the semiconductor of the emitting portion is such that the light emitted by the LED belongs to the UV range, in particular between 210 nm and 340 nm or between 210 nm and 400 nm, and more particularly in the UV-C range, that is to say between 210 nm and 280 nm. For example, the LED may emit light of wavelength comprised between 260 nm and 270 nm in order for this light emitted by the LED to have bactericidal properties, it being possible for the LED to be used for example for air and/or water purification applications. According to another example, the semiconductor of the emitting portion may be such that the wavelength of the light emitted from the active zone of the LED is equal to 315 nm, making the LED suitable for medical use, for example for treating psoriasis. Furthermore, the structure of this LED makes it possible to attain very short wavelengths, for example equal to 210 nm.

The LED may furthermore comprise:

a portion of AlGaN not intentionally doped disposed between the first portion and the active zone, and/or

a portion of AlGaInN not intentionally doped disposed between the active zone and the second portion.

This configuration enables the charge carrier recombination zone to be better spatially defined. Furthermore, the portion of AlGaInN not intentionally doped disposed between the active zone and the second portion serves as electron blocking layer (EBL) to avoid excess electrons in the p-doped zone.

A semiconductor not intentionally doped, or nid, comprises a semiconductor that has not undergone a doping step during which doping atoms are introduced into the semiconductor.

The LED may furthermore comprise a substrate such that the first portion is disposed between the substrate and the active zone.

Moreover, the LED may further comprise at least one portion of n-doped GaN disposed between the substrate and the first portion. The n-doped GaN portion in this case makes it possible to initiate growth of nanowires before the deposit of portions of AlGaN. It in particular makes it possible to use any type of substrate: semiconductor, amorphous or metallic.

The diode may comprise a stack of layers forming the different portions of the diode, or several nanowires disposed side by side and forming together the different portions of the diode.

When the diode comprises several nanowires disposed side by side and together and forming the different portions of the diode, the lateral dimensions of the parts of the nanowires forming the second portion are such that they form, at the tops of the nanowires, a semiconductor layer. In this case, the tops of the nanowires have greater lateral dimensions bringing these tops into contact with each other so as to form the semiconductor layer. This semiconductor layer may advantageously form a base for producing the third n-doped semiconductor portion and the electrically conductive and optically transparent layer. The lateral dimensions of the nanowires are the dimensions of the nanowires that are substantially perpendicular to the length, the length being their largest dimension. As a variant, this base for producing the electrically conductive and optically transparent layer and optionally the third n-doped semiconductor portion could be formed in another way, for example by filling the space between the nanowires with an insulating material that is not optically absorbent.

The active zone may comprise one or more layers of quantum dots each formed by an emitting layer disposed between two barrier layers.

There is also provided a method of producing a light-emitting diode, comprising at least:

producing a first n-doped semiconductor portion;

on the first portion, producing an active zone comprising at least one semiconductor emitting portion;

producing a second p-doped semiconductor portion on the active zone;

wherein

the semiconductors of the first portion and of the emitting layer comprise compounds comprising nitrogen atoms as well as atoms of aluminum and/or of gallium;

the semiconductor of the second portion comprises Al_{X2}Ga_{(1-X2-Y2)}In_{Y2}N that is p-doped with magnesium atoms, with X2>0, Y2>0 and X2+Y2≤1, and in which the atomic concentration of magnesium is greater than 10¹⁷ at/cm³.

There is also provided a method of producing a light-emitting diode, comprising at least:

producing a first n-doped semiconductor portion;

on the first portion, producing an active zone comprising at least one semiconductor emitting portion;

producing a second p-doped semiconductor portion on the active zone;

producing, on the second portion, a layer that is electrically conductive and optically transparent at least to a wavelength of the UV range configured to be emitted from the emitting portion;

wherein

the semiconductors of the first portion and of the emitting layer comprise compounds comprising nitrogen atoms as well as atoms of aluminum and/or of gallium;

the semiconductor of the second portion comprises Al_{X2}Ga_{(1-X2-Y2)}In_{Y2}N that is p-doped with magnesium atoms, with X2>0, Y2>0 and X2+Y2≤1, and in which the atomic concentration of magnesium atoms is greater than 10¹⁷ at/cm³;

the electrically conductive layer comprises doped diamond.

The growth of this layer may be for example carried out by chemical vapor deposition (i.e. CVD). A continuous layer of polycrystalline diamond is then obtained by coalescence of the diamond nanocrystals that have grown on the surface.

Production of the second portion may comprise implementation of MetalOrganic Chemical Vapor Deposition (or MOCVD) and/or Molecular Beam Epitaxy (MBE).

The method may furthermore comprise, after producing the second portion:

producing a third n-doped semiconductor portion on the second portion, the semiconductor of the third portion comprising Al_{X3}Ga_{(1-X3-Y3)}In_{Y3}N, with X3>0, Y3>0 and X3+Y3≤1, and/or

producing, on the second portion, a layer that is electrically conductive and optically transparent at least at a wavelength configured to be emitted from the emitting portion.

When the third portion and the electrically conductive layer are produced, the third portion may be produced before the electrically conductive layer, the latter being produced next on the third portion.

The method may further comprise, after producing the second portion, a step of activating the dopants of the semiconductor of the second portion including thermal annealing and/or electron beam irradiation of the second portion.

### BRIEF DESCRIPTION OF THE DRAWINGS

The present invention will be better understood on reading the description of the example embodiments given purely by way of indication and which is in no way limiting, with reference to the accompanying drawings in which:

FIG. 1 shows an LED according to the prior art;

FIG. 2 shows an LED of the present invention according to a first embodiment;

FIG. 3 shows an LED of the present invention according to a second embodiment;

FIG. 4 shows an LED of the present invention according to a third embodiment.

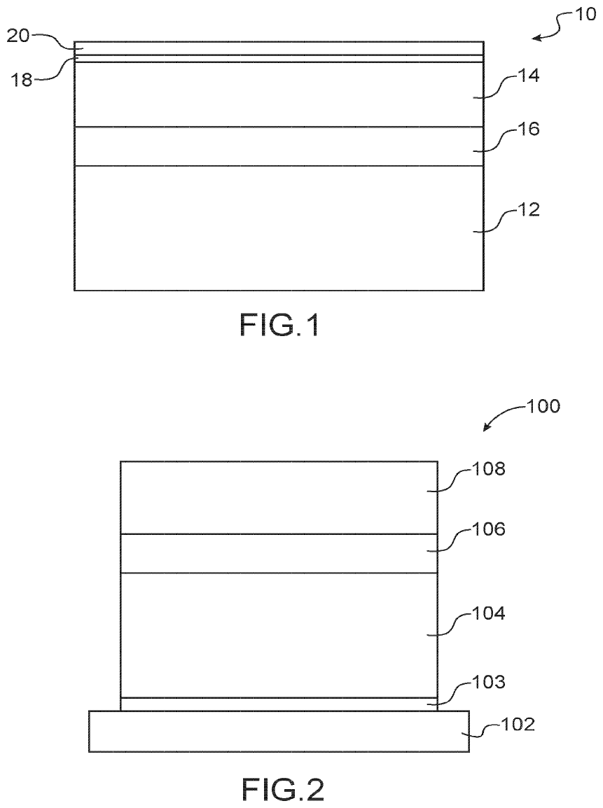

Parts that are identical, similar or equivalent of the various drawings described below bear the same numerical references so as to identify the passage from one drawing to the other.

The various parts shown in the drawings are not necessarily at a uniform scale, so as to render the drawings easier to read.

The various possibilities (variants and embodiments) must be understood is not being exclusive of each other and may be combined between each other.

### DETAILED DESCRIPTION OF SPECIFIC EMBODIMENTS

A LED 100 according to a first embodiment is described below in relation to FIG. 2. In this first embodiment, the various portions of materials forming the LED 100 are produced in the form of layers stacked on top of each other and produced by the successive implementation of epitaxy steps.

The LED 100 comprises a substrate 102. In this first embodiment, the substrate 102 comprises for example sapphire. Other types of substrate may be used, comprising for example a semiconductor material.

Advantageously, the LED 100 comprises a portion of n-doped GaN formed on the substrate 103.

The LED 100 also comprises a first portion 104 of n-doped semiconductor disposed on portion 103 (or directly on the substrate 102 when the LED 100 does not comprise the portion 103). The semiconductor of the first portion 104 comprises a compound comprising nitrogen atoms as well as atoms of aluminum and/or of gallium. The semiconductor of the first portion 104 comprises Al_{X1}Ga_{(1-X1)}N, with 0≤X1≤1, preferably with 0.7 X1 0.8. The semiconductor of the first portion 104 may also comprise indium atoms, it being possible in this case for the compound of the first portion 104 to comprise AlGaInN or InGaN.

According to an example embodiment, the n-type doping of the semiconductor of the first portion 104 is obtained by incorporating silicon atoms into the semiconductor of the first portion 104 at the time one of the growth of that semiconductor. The concentration of dopants in the semiconductor of the first portion 104 is for example comprised between 10¹⁷ at/cm³ and 10¹⁹ at/cm³.

The thickness of the first portion 104 is for example equal to 1 μm, and more generally is comprised between 0.5 and 5 μm.

LED 100 also comprises an active zone 106 disposed on the first portion 104. This active zone 106 comprises at least one semiconductor emitting portion from which light is configured to be emitted. The semiconductor of the emitting portion comprises a compound comprising nitrogen atoms as well as atoms of aluminum and/or of gallium. For example, the semiconductor of the emitting portion comprises Al_{X4}Ga_{(1-X4)}N, with X4<X1, and preferably X4≤0.1×X1. This semiconductor is not intentionally doped, that is to say that during production of the LED 100, it is not subjected to a step of introducing doping atoms into the semiconductor.

The thickness of the active zone 106 is for example equal to 100 nm, and more generally is comprised between approximately 100 nm and 300 nm.

Advantageously, the value of X4 is chosen such that the wavelength of the light emitted from the emitting portion of the active zone 106 belongs to the UV range, in particular between approximately 210 nm and 340 nm, and more particularly to the UV-C range (that is to say between 210 nm and 280 nm), which corresponds to X4 such that 0.7<X4<1.

According to a variant embodiment, the LED 100 may comprise a portion of AlGaN not intentionally doped disposed between the first portion 104 and the active zone 106, and of which the thickness is for example equal to 20 nm. This portion of AlGaN is not shown in FIG. 2.

The LED 100 also comprises a second portion 108 of p-doped semiconductor disposed on the active zone 106. The semiconductor of the second portion 108 comprises Al_{X2}Ga_{(1-X2-Y2)}In_{Y2}N that is p-doped by magnesium atoms, with X2>0, Y2>0 and X2+Y2≤1. Advantageously, the semiconductor of the second portion 108 is such that X2=X1. Furthermore, it is advantageous to have 0<Y2≤0.01, and preferably Y2=0.001.

The concentration of dopants in the semiconductor of the second portion 108 is for example comprised between approximately 10¹⁸ at/cm³ and 10²¹ at/cm³.

The thickness of the second portion 108 is for example equal to 1 μm, and more generally is between approximately 0.2 μm and 1 μm.

The second portion 108 may be produced by MOCVD or MBE

On growth by MBE the streams of the different chemical elements of the semiconductor are sent onto the growth surface. For the growth of the semiconductor of the second portion 108, the streams of aluminum, active nitrogen, indium and optionally of gallium are sent onto the growth surface which comprises the upper surface of the active zone 106. A stream of magnesium is also sent in order for the semiconductor produced to be p-doped with magnesium atoms. The values of these streams, that is to say the quantity of atoms sent of each of these chemical elements. are chosen according to the composition desired for the semiconductor of the second portion 108 and in particular such that the atomic concentration of indium be comprised between 0 and 1% and preferably equal to 0.1%. In the presence of this is of indium, the atomic concentration of magnesium in the semiconductor of the second portion 108 is proportional to the quantity of indium incorporated in that semiconductor and is for example comprised between 10¹⁷ at/cm³ and 10²¹ at/cm³, and advantageously comprised between 10²⁰ at/cm³ and 10²¹ at/cm³, i.e. an atomic concentration of magnesium comprised between 0.1% and 1%.

Upon growth by MOCVD, the constituents used for the growth of the semiconductor are organometallic precursors, for example trimethylaluminum or triethylaluminum serving as a source of aluminum, ammoniac serving as a source of nitrogen, trimethylindium or triethylindium serving as a source of indium, and optionally trimethylgallium or triethylgallium serving as a source of gallium. The magnesium atoms are obtained by an appropriate precursor, for example a solution of magnesocene or Mg(Cp)₂. The concentrations of indium and of magnesium that can be obtained with MOCVD may be similar to those obtained with MBE.

According to a variant embodiment, the LED 100 may comprise a portion of AlGaInN not intentionally doped disposed between the active zone 106 and the second portion 108, and of which the thickness is for example equal to 20 nm. This portion of AlGaInN is not shown in FIG. 2. The portion of AlGaInN not intentionally doped serves is an electron blocking layer which makes it possible to avoid excess electrons in the p-doped zone and promote recombination of the charge carriers in the active zone.

For this first embodiment, the different portions of LED 100 may be produced by implementing several successive steps of epitaxy.

After producing the second portion 108, a step of activating the p-type dopants (that is to say the magnesium atoms) present in the semiconductor of the second portion 108 is implemented. This activation step may comprise the implementation of heat annealing and/or irradiation by electron beam of the second portion 108. The heat annealing is for example carried out at a temperature comprised between 100° C. and 1000° C., and preferably equal to 700° C. The electron beam irradiation consists of sending one or more beams of electrons onto the LED 100, through the upper face of the LED 100 formed by the second portion 108, the energy of the electrons being chosen to limit their penetration into the semiconductor of the second portion 108 in order for the electrons not to reach the materials located under the second portion 108. This energy of the electrons is for example equal to 3 keV, or more generally comprised between approximately 2 keV and 30 keV and chosen in particular according to the thickness of the second portion 108. The dose is set by the value of the electron beam current and can vary between 1 mA/cm² and 20 mA/cm², and is preferably equal to 7 mA/cm². This electron irradiation is carried out for a period for example equal to 10 minutes.

Although not shown in FIG. 2, the LED 100 may comprise a layer that is electrically conductive and optically transparent at least at a wavelength in the UV range configured to be emitted from the emitting portion of the LED 100. In this case, the second portion 108 is disposed between that electrically conductive layer and the active zone 106. This electrically conductive layer may comprise doped diamond.

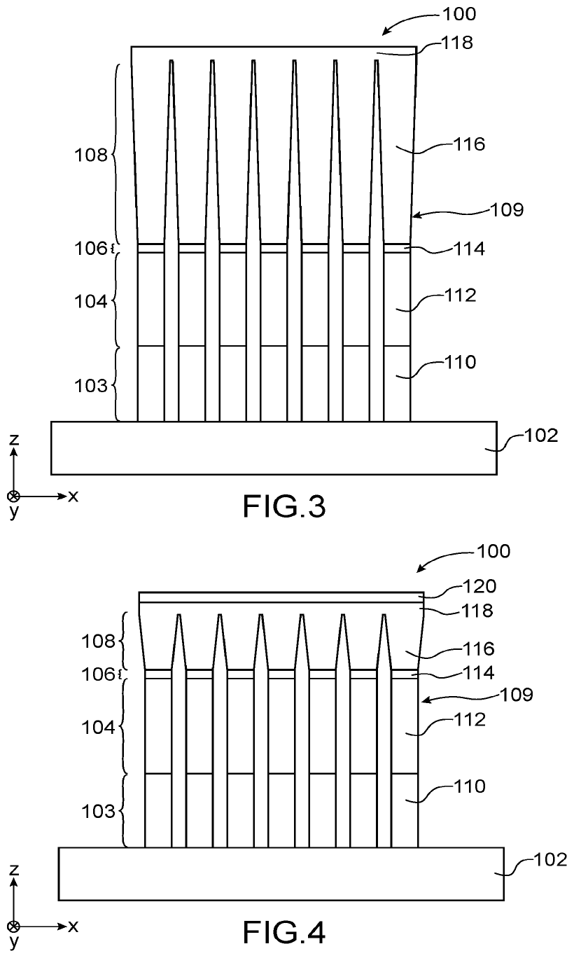

A LED 100 according to a second embodiment is described below in relation to FIG. 3. In this second embodiment, the various portions of materials of the LED 100 are formed by nanowires 109 disposed side by side on the substrate 102. Each nanowire 109 comprises several parts successively produced, for example by epitaxy, comprising materials of various compositions and forming the various portions of materials of the LED 100. In the description below, the term “length” of each part of the nanowires 109 is the dimension of that part of the nanowire 109 that is perpendicular to the surface on which the nanowires 109 are formed, and which is parallel to the z-axis represented in FIG. 3. The lengths of the various parts of the nanowires match the thicknesses of the various portions of the LED 100.

As in the first embodiment, the LED 100 comprises the substrate 102. In this second embodiment, the substrate 102 an electrically conductive material, for example such as n-doped silicon.

The nanowires 109 of the LED 100 are produced here by growth from a front face of the substrate 102, i.e. by spontaneous nucleation or, preferably, on parts of the substrate 102 defined in advance by masking. The nanowires 109 of the LED 100 are for example produced by MBE.

Each nanowire 109 comprises a first part 110 formed on the substrate 102 and comprising n-doped GaN. These first parts 110 together form the portion 103 of n-doped GaN. Each first part 110 for example has a length comprised between 100 nm and 500 nm.

Each nanowire 109 also comprises a second part 112 formed on the first part 110. These second parts 112 together form the first portion 104 of n-doped semiconductor. The semiconductor of the second portions 112 one of the nanowires 109 comprises a compound comprising nitrogen atoms as well as atoms of aluminum and/or of gallium. The semiconductor of the second portions 112 comprises Al_{X1}Ga_{(1-X1)}N, with 0≤X1≤1, with preferably 0.7≤X1≤0.8.

According to an example embodiment, the n-type doping of the semiconductor of the second parts 112 of the nanowires 109 is obtained by incorporating silicon atoms into the semiconductor of these second parts 112 during their growth. The concentration of dopants in the semiconductor of the second parts 112 of the nanowires 109 is for example comprised between 10¹⁷ at/cm³ and 10¹⁸ at/cm³, and more generally between 10¹⁶ at/cm³ and 10²⁰ at/cm³.

Each second part 112 for example has a length comprised between 100 nm and 500 nm.

According to a variant embodiment, the nanowires 109 do not comprise the first parts 110. In this case, the material of the nanowires 109 formed against the substrate 102 matches that of the second parts 112.

Each nanowire 109 also comprises a third part 114 formed on the second part 112. The third parts 114 of the nanowires 109 together form the active zone 106 of the LED 100, and form in particular an semiconductor emitting portion of the active zone 106 from which light is configured to be emitted. The semiconductor of the emitting portion comprises a compound comprising nitrogen atoms as well as atoms of aluminum and/or of gallium. For example, the semiconductor of the emitting portion comprises Al_{X4}Ga_{(1-X4)}N, with X4<X1, and preferably X4≤0.1×X1. This semiconductor is not intentionally doped, that is to say that during production of the LED 100, it is not subjected to a step of introducing doping atoms into the semiconductor.

Each third part 114 for example has a length equal to 100 nm.

According to a variant embodiment, each nanowire 109 may comprise a portion of AlGaN not intentionally doped disposed between the second part 112 and the third part 114, and of which the thickness is for example equal to 20 nm. This portion of AlGaN is not shown in FIG. 3.

Each nanowire 109 also comprises a fourth part 116 formed on the third part 114. The fourth parts 116 of the nanowires 109 together form the second portion 108 of p-doped semiconductor disposed on the active zone 106. The semiconductor of the fourth parts 116 comprises Al_{X2}Ga_{(1-X2-Y2})In_{Y2}N that is p-doped by magnesium atoms, with X2>0, Y2>0 and X2+Y2≤1. Advantageously, the semiconductor of the fourth parts 116 is such that X2=X1. Furthermore, it is advantageous to have 0<Y2≤0.01, and preferably Y2=0.001.

The concentration of dopants in the semiconductor of the second portion 108 is for example comprised between approximately 10¹⁸ at/cm³ and 10²¹ at/cm³.

Each fourth part 116 for example has a length comprised between 100 nm and 500 nm.

According to a variant embodiment, each nanowire 109 may comprise a portion of AlGaInN not intentionally doped disposed between the third part 114 and the fourth part 116, and of which the thickness is for example equal to 20 nm. This portion of AlGaInN is not shown in FIG. 3.

Advantageously, the fourth parts 116 of the nanowires 109 are produced such that at their top, these fourth parts 116 have lateral dimensions (dimensions in the plane (X,Y)) that increase, and such that they meet in being physically in contact with each other. This configuration makes it possible, at the top of the nanowires 109, to form a layer 118 comprising the material of the fourth parts 116 of the nanowires 109. This configuration is for example obtained, on growing the nanowires 109 by MBE, by modifying the ratio between the metallic streams (constituting the streams of aluminum and indium, and possibly the stream of gallium) and the stream of nitrogen. It is for example possible to increase the metallic stream by 50% to obtain the layer 118. This makes it possible to deposit the p-type doped material on the side of the nanowires 109 while minimizing the risk of electrical short-circuit with the bottom part of the LED 100. This layer 118 is for example obtained when the spacing between two nanowires 109 is less than approximately twice the diameter of one of the nanowires 109.

As for the first embodiment, after producing the fourth parts 116 of the nanowires 109 (and possibly the layer 118 if such a layer is produced), a step of activating the p-type dopants (that is to say the magnesium atoms) present in the semiconductor of the fourth parts 116 of the nanowires 109 is performed. This activating step may comprise implementing heat annealing and/or irradiation by electron beam(s), in similar manner to that described above for the first embodiment.

Although not shown in FIG. 3, the LED 100 according to this second embodiment may comprise a layer that is electrically conductive and optically transparent at least at a wavelength in the UV range configured to be emitted from the emitting portion of the LED 100. In this case, this electrically conducting layer is disposed on layer 118. This electrically conductive layer may comprise doped diamond.

A LED 100 according to a third embodiment is described below in relation to FIG. 4.

As in the second embodiment, the various portions of materials forming the LED 100 are formed by nanowires 109 disposed side by side on the substrate 102. Each nanowire 109 comprises several successively produced parts, comprising materials of various compositions and forming the various portions of materials of the LED 100.

The nanowires 109 of the LED 100 according to the third embodiment are similar to those described previously for the LED 100 according to the second embodiment, and comprise parts 110, 112, 114 and 116 and also form, at their tops, layer 118.

The LED 100 according to this third embodiment also comprises, on layer 118, a layer of n-doped Al_{X3}Ga_{(1-X3-Y3)}In_{Y3}N with X3>0, Y3>0 and X3+Y3≤1. This layer is here called third n-doped semiconductor portion of the LED 100 and is not visible in FIG. 4. Advantageously, the atomic concentration X3 of aluminum in the semiconductor of the third portion is equal to the atomic concentration X1 of aluminum in the semiconductor of the first portion 104. The n-type dopants present in the semiconductor of the third portion for example comprise silicon or germanium atoms. The concentration of dopants in the semiconductor of the third portion is for example comprised between approximately 10¹⁷ at/cm³ and 10²⁰ at/cm³. The thickness of the third portion is for example equal to 100 nm, and more generally is comprised between approximately 50 nm and 200 nm. This third portion makes it possible to achieve injection of current by tunnel effect in the LED 100.

It is also possible for the atomic concentration X3 of aluminum in the semiconductor of the third portion to be less than the atomic concentration X1 of aluminum in the semiconductor of the first portion 104. This makes it possible, in the semiconductor of the third portion, to attain a higher level of doping while ensuring the transparency of this third portion with regard to the emission wavelength of the LED 100 when the LED 100 emits in the UV range.

As a variant, it is possible for the LED 100 not to comprise this third portion and it may comprise a layer 120 comprising not AlGaInN but another material that is electrically conductive and transparent to the wavelength emitted by the LED 100 (here a wavelength of the UV range). For example, the layer 120 may comprise a layer of electrically conducting diamond, for example doped polycrystalline diamond of which the thickness is for example equal to 100 nm. More generally, the thickness of the layer 120 is comprised between 30 nm and 500 nm.

Whatever the material of the layer 120, this layer 120 may be present in the LED 100 according to the first embodiment. Furthermore, when the LED 100 comprises nanowires 109 which do not form layer 118 at their tops, it is possible for each of the nanowires 109 to comprise, at its top, a part comprising n-doped Al_{X3}Ga_{(1-X3-Y3)}In_{Y3}N, with X3>0, Y3>0 and X3+Y3≤1 and forming the third portion already described.

This layer 120 makes it possible to form a transparent electrode on the structure of the LED 100 which makes it possible to facilitate contact formation while remaining transparent at the emitted wavelength. It also promotes obtaining even spreading of the current stream lines over the whole surface of the injection layer of the LED 100, which promotes optimization of the LED 100.

In the three embodiments described earlier, the active zone 106 comprises an emitting portion comprising a compound formed from nitrogen atoms as well as atoms of aluminum and/or gallium. As a variant, it is possible for the active zone 106 of the LED 100 to comprise one or more quantum wells each formed from an emitting layer disposed between two barrier layers. In this case, the semiconductor of the emitting layer or of each emitting layer and the semiconductor of each of the barrier layers may comprise AlGaN, with, however, in the semiconductor of the emitting layers, an atomic concentration of aluminum less than that in the semiconductor of the barrier layers, and preferably less than 10% of that in the semiconductor of the barrier layers.

As a variant, it is possible for the active zone 106 of the LED 100 to comprise one or more quantum dots each formed from an emitting layer disposed between two barrier layers. In this case, the semiconductor of the emitting layer or of each emitting layer and the semiconductor of each of the barrier layers may comprise AlGaN, with, however, in the semiconductor of the emitting layers, an atomic concentration of aluminum less than that in the semiconductor of the barrier layers, and preferably 10% less than that in the semiconductor of the barrier layers. The emitting layer or each of the emitting layers may in this case also comprise monoatomic layers of GaN and AlN superposed such that the proportion, or composition, of aluminum in the average alloy of these layers is less than that in the semiconductor of the barrier layers, and preferably less than 10% of that in the semiconductor of the barrier layers. The proportion of an atomic element of the “average alloy” of these layers is calculated by taking into account the proportion of that element in each of these layers and by weighting these concentrations by the thicknesses of the layers. For example, considering a stack of layers comprising a layer of GaN of thickness equal to 2 mm and a layer of AlN of thickness equal to 1 nm, this stack of layers being repeated several times, the proportion of aluminum in the average alloy is 33%, that is to say that the average alloy is

A1_{0,33}Ga_{0,67}N. In this case, when this proportion of aluminum is preferably less than 10% of that in the semiconductor of the barrier layers, the proportion of aluminum in the semiconductor of the barrier layers is 33%+3.3%=36.3%.

1. A light-emitting diode, comprising:
a first portion, which is an n-doped semiconductor;
a second portion, which is a p-doped semiconductor;
an active zone disposed between the first and second portions, the active zone comprising an emitting semiconductor portion;
an electrically conductive layer that is optically transparent to at least one UV wavelength which the emitting semiconductor portion is configured to emit, the electrically conductive layer being such that the second portion is disposed between the electrically conductive layer and the active zone;
wherein the electrically conductive layer comprises doped diamond,
wherein the semiconductors of the first portion and of the emitting semiconductor portion comprise a compound comprising (i) a nitrogen atom and (ii-a) an aluminum atom and/or (ii-b) a gallium atom,
wherein the p-doped semiconductor of the second portion comprises
Al_{X2}Ga_{(1-X2-Y2)}In_{Y2}N
that is p-doped with magnesium atoms,
wherein
X2>0,
Y2>0,
X2+Y2<1, and
an atomic concentration of the magnesium atoms is greater than 10¹⁷ at/cm³;

2. The diode of claim 1,
wherein 0<Y2≤0.01.

3. The diode of claim 1, further comprising:
a third portion, which is an n-doped semiconductor,
wherein the third portion is disposed between the electrically conductive layer and the second portion, and
wherein the n-doped semiconductor of the third portion comprises
Al_{X3}Ga_{(1-X3-Y3)}In_{Y3}N,
wherein
X3>0,
Y3>0, and
X3+Y3≤1.

4. The diode of claim 1, wherein the n-doped semiconductor of the first portion comprises
Al_{X1}Ga_{(1-X1)}N,
wherein
0.7≤X1≤0.8.

5. The diode of claim 1, wherein the semiconductor of the emitting semiconductor portion comprises
Al_{X4}Ga_{(1-X4)}N,
wherein
X4≤0.9×X1.

6. The diode of claim 1, further comprising
an AlGaN portion not intentionally doped,
wherein the AlGaN portion is disposed between the first portion and the active zone.

7. The diode of claim 1, further comprising:
a substrate,
wherein the first portion is disposed between the substrate and the active zone.

8. The diode of claim 7, further comprising:
an n-doped GaN portion disposed between the substrate and the first portion.

9. The diode of claim 1, comprising a stack of layers forming the portions of the diode, or several nanowires disposed side by side and forming together the portions of the diode.

10. The diode of claim 9, comprising the several nanowires,
wherein lateral dimensions of parts of the nanowires form the second portion so as to form, at tops of the nanowires, a semiconductor layer.

11. The diode of claim 1, wherein the active zone comprises a layer comprising quantum dots, each formed by an emitting layer disposed between two barrier layers.

12. A method of producing a light-emitting diode, the method comprising:
producing a first portion, which is an n-doped semiconductor;
on the first portion, producing an active zone comprising a semiconductor emitting portion;
producing a second portion, which is a p-doped semiconductor, on the active zone;
producing, on the second portion, an electrically conductive layer that is optically transparent at least to a UV wavelength that the emitting semiconductor portion is configured to emit;
wherein the electrically conductive layer comprises doped diamond,
wherein the semiconductors of the first portion and of the emitting semiconductor portion comprise a compound comprising (i) a nitrogen atom and (ii-a) an aluminum atom and/or (ii-b) a gallium atom,
wherein the p-doped semiconductor of the second portion comprises
Al_{X2}Ga_{(1-X2-Y2)}In_{Y2}N,
that is p-doped with magnesium atoms,
wherein
X2>0,
Y2>0, and
X2+Y2≤1, and
an atomic concentration of the magnesium atoms is greater than 10¹⁷ at/cm³.

13. The method of claim 12, wherein the producing of the second portion comprises implementing metalorganic chemical vapor deposition and/or molecular beam epitaxy.

14. The method of claim 12, further comprising, after the producing of the second portion:
producing a third portion, which is an n-doped semiconductor, on the second portion,
wherein the n-doped semiconductor of the third portion comprises
Al_{X3}Ga_{(1-X3 -Y3)}In_{Y3}N,
wherein
X3>0,
Y3>0, and
X3+Y3≤1,
wherein the electrically conducting layer is then produced on the third portion.

15. The method of claim 12, further comprising, after the producing of the second portion:
activating dopants of the p-doped semiconductor of the second portion comprising thermal annealing and/or electron beam irradiating the second portion.

16. The diode of claim 1, wherein the atomic concentration of magnesium in the semiconductor of the second portion is in a range of from 10²⁰ to 10²¹ at/cm³.

17. The diode of claim 2, wherein the atomic concentration of magnesium in the semiconductor of the second portion is in a range of from 10²⁰ to 10²¹ at/cm³.

18. The diode of claim 1, further comprising:
an AlGaInN portion not intentionally doped,
wherein the AlGaInN portion is disposed between the active zone and the second portion.

19. The diode of claim 6, further comprising:
an AlGaInN portion not intentionally doped,
wherein the AlGaInN portion is disposed between the active zone and the second portion.
